(19) United States
(12) Patent Application Publication
(10) Pub. No.: US 2026/0252750 A1
(43) Pub. Date: Aug. 27, 2026

(54) CREATING COMPOSITE MATERIAL PROPERTIES FOR DIGITAL TWIN BASED WIRELESS SIMULATION

(71) Applicant: QUALCOMM Incorporated, San Diego, CA (US)

(72) Inventors: Parag Mohan KANADE, San Diego, CA (US); Lokesh JAIN, San Diego, CA (US); Satyam GABA, San Diego, CA (US); Sony AKKARAKARAN, Poway, CA (US); Tao LUO, San Diego, CA (US)

(21) Appl. No.: 19/429,905

(22) Filed: Dec. 22, 2025

Related U.S. Application Data
(60) Provisional application No. 63/763,738, filed on Feb. 26, 2025.

(51) Int. Cl. G06F 30/13; G06T 17/20

(52) U.S. Cl. CPC G06F 30/13; G06T 17/205

(57) ABSTRACT

Methods, systems, and devices for digital twin creation are described. A digital twin server may determine a ratio of different surfaces, and create a composite material which combines the material properties of the multiple detected materials in accordance with the determined ratio. The digital twin server may develop a probabilistic distribution-based material model, which may combine ethe properties of individual materials. The digital twin server may identify any meshes a three-dimensional (3D) model that are larger than a first area threshold. Of these larger meshes, the digital twin server may determine which meshes cover multiple materials. The area of such materials may be calculated for the respective mesh, and if the percentage of area of the material is less than a configured material threshold, the digital twin server may subdivide the mesh.

### CROSS REFERENCES

The present Application for Patent claims benefit of U.S. Provisional Patent Application No. 63/763,738 by KANADE et al., entitled “CREATING COMPOSITE MATERIAL PROPERTIES FOR DIGITAL TWIN BASED WIRELESS SIMULATION,” filed Feb. 26, 2025, assigned to the assignee hereof, and expressly incorporated herein.

### FIELD OF TECHNOLOGY

The following relates to digital twin creation, including creating composite material properties for digital twin based wireless simulation.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The systems, methods, and devices of this disclosure each have several innovative aspects, no single one of which is solely responsible for the desirable attributes disclosed herein.

A method for digital twin creation by an apparatus is described. The method may include obtaining a three-dimensional model of a geographic area, where at least a first portion of the three-dimensional model includes a first material corresponding to a first set of properties and a second material corresponding to a second set of properties, computing a ratio between the first material and the second material in at least the first portion of the three-dimensional model, generating a composite material corresponding to a third set of properties by combining the first set of properties and the second set of properties in accordance with the ratio, and outputting a digital twin associated with the geographic area based on the composite material and the third set of properties.

An apparatus for digital twin creation is described. The apparatus may include one or more memories storing processor executable code, and one or more processors coupled with the one or more memories. The one or more processors may individually or collectively be operable to execute the code to cause the apparatus to obtain a three-dimensional model of a geographic area, where at least a first portion of the three-dimensional model includes a first material corresponding to a first set of properties and a second material corresponding to a second set of properties, compute a ratio between the first material and the second material in at least the first portion of the three-dimensional model, generate a composite material corresponding to a third set of properties by combining the first set of properties and the second set of properties in accordance with the ratio, and output a digital twin associated with the geographic area based on the composite material and the third set of properties.

Another apparatus for digital twin creation is described. The apparatus may include means for obtaining a three-dimensional model of a geographic area, where at least a first portion of the three-dimensional model includes a first material corresponding to a first set of properties and a second material corresponding to a second set of properties, means for computing a ratio between the first material and the second material in at least the first portion of the three-dimensional model, means for generating a composite material corresponding to a third set of properties by combining the first set of properties and the second set of properties in accordance with the ratio, and means for outputting a digital twin associated with the geographic area based on the composite material and the third set of properties.

A non-transitory computer-readable medium storing code for digital twin creation is described. The code may include instructions executable by one or more processors to obtain a three-dimensional model of a geographic area, where at least a first portion of the three-dimensional model includes a first material corresponding to a first set of properties and a second material corresponding to a second set of properties, compute a ratio between the first material and the second material in at least the first portion of the three-dimensional model, generate a composite material corresponding to a third set of properties by combining the first set of properties and the second set of properties in accordance with the ratio, and output a digital twin associated with the geographic area based on the composite material and the third set of properties.

Some examples of the method, apparatus, and non-transitory computer-readable medium described herein may further include operations, features, means, or instructions for assigning the composite material corresponding to the third set of properties to at least the first portion of the three-dimensional model, where outputting the digital twin may be based on the assigning.

In some examples of the method, apparatus, and non-transitory computer-readable medium described herein, computing the composite material may include operations, features, means, or instructions for generating a model of the composite material corresponding to the third set of properties via a machine learning model.

Some examples of the method, apparatus, and non-transitory computer-readable medium described herein may further include operations, features, means, or instructions for obtaining the first set of properties corresponding to the first material and the second set of properties for responding to the second material from a database, where generating the composite material corresponding to the third set of properties may be based on obtaining the first set of properties and the second set of properties from the database.

Some examples of the method, apparatus, and non-transitory computer-readable medium described herein may further include operations, features, means, or instructions for obtaining a first set of multiple measurements corresponding to the first material, the first set of properties based on the first set of multiple measurements, obtaining a second set of multiple measurements corresponding to the second material, the second set of properties based on the second set of multiple measurements, and storing the first set of properties and the second set of properties in the database based on obtaining the first set of multiple measurements and the second set of multiple measurements.

In some examples of the method, apparatus, and non-transitory computer-readable medium described herein, the first material and the second material may be internal or external to one or more structures of the three-dimensional model.

A method for digital twin creation by an apparatus is described. The method may include obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value, calculating a percentage of the first material in the first mesh, subdividing the first mesh into a first portion corresponding to the first material and the second material and a second portion corresponding to the second material based on the percentage of the first material in the first mesh satisfying a second threshold value, and outputting a digital twin associated with the geographic area based on the first set of properties corresponding to the first portion of the first mesh and the second set of properties corresponding to the second portion of the first mesh.

An apparatus for digital twin creation is described. The apparatus may include one or more memories storing processor executable code, and one or more processors coupled with the one or more memories. The one or more processors may individually or collectively be operable to execute the code to cause the apparatus to obtain a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value, calculate a percentage of the first material in the first mesh, subdivide the first mesh into a first portion corresponding to the first material and the second material and a second portion corresponding to the second material based on the percentage of the first material in the first mesh satisfying a second threshold value, and output a digital twin associated with the geographic area based on the first set of properties corresponding to the first portion of the first mesh and the second set of properties corresponding to the second portion of the first mesh.

Another apparatus for digital twin creation is described. The apparatus may include means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value, means for calculating a percentage of the first material in the first mesh, means for subdividing the first mesh into a first portion corresponding to the first material and the second material and a second portion corresponding to the second material based on the percentage of the first material in the first mesh satisfying a second threshold value, and means for outputting a digital twin associated with the geographic area based on the first set of properties corresponding to the first portion of the first mesh and the second set of properties corresponding to the second portion of the first mesh.

A non-transitory computer-readable medium storing code for digital twin creation is described. The code may include instructions executable by one or more processors to obtain a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value, calculate a percentage of the first material in the first mesh, subdivide the first mesh into a first portion corresponding to the first material and the second material and a second portion corresponding to the second material based on the percentage of the first material in the first mesh satisfying a second threshold value, and output a digital twin associated with the geographic area based on the first set of properties corresponding to the first portion of the first mesh and the second set of properties corresponding to the second portion of the first mesh.

Some examples of the method, apparatus, and non-transitory computer-readable medium described herein may further include operations, features, means, or instructions for assigning the first set of properties to the first portion of the first mesh and assigning the second set of properties to the second portion of the first mesh, where the digital twin may be based on assigning the first set of properties to the first portion of the first mesh and assigning the second set of properties to the second portion of the first mesh.

In some examples of the method, apparatus, and non-transitory computer-readable medium described herein, subdividing the first mesh may include operations, features, means, or instructions for subdividing the first mesh multiple times until a size of the resulting subdivision of the first mesh fails to satisfy the first threshold, or the percentage of the first material in a resulting subdivision of the first mesh fails to satisfy the second threshold value.

In some examples of the method, apparatus, and non-transitory computer-readable medium described herein, subdividing the first mesh may include operations, features, means, or instructions for subdividing the first mesh based on an object boundary within the first mesh.

In some examples of the method, apparatus, and non-transitory computer-readable medium described herein, subdividing the first mesh may include operations, features, means, or instructions for subdividing the first mesh based on a mathematical division into equal portions.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a wireless communications system that supports creating composite material properties for digital twin based wireless simulation in accordance with one or more aspects of the present disclosure.

FIG. 2 shows an example of a composite material generation scheme that supports creating composite material properties for digital twin based wireless simulation in accordance with one or more aspects of the present disclosure.

FIG. 3 shows an example of a composite material division scheme that supports creating composite material properties for digital twin based wireless simulation in accordance with one or more aspects of the present disclosure.

FIGS. 4 and 5 show block diagrams of devices that support creating composite material properties for digital twin based wireless simulation in accordance with one or more aspects of the present disclosure.

FIG. 6 shows a block diagram of a digital twin creation entity that supports creating composite material properties for digital twin based wireless simulation in accordance with one or more aspects of the present disclosure.

FIG. 7 shows a diagram of a system including a UE that supports creating composite material properties for digital twin based wireless simulation in accordance with one or more aspects of the present disclosure.

FIG. 8 shows a diagram of a system including a network entity that supports creating composite material properties for digital twin based wireless simulation in accordance with one or more aspects of the present disclosure.

FIGS. 9 and 10 show flowcharts illustrating methods that support creating composite material properties for digital twin based wireless simulation in accordance with one or more aspects of the present disclosure.

### DETAILED DESCRIPTION

Wireless communications systems may be modeled by digital twins, increasing the effectiveness and efficiency of wireless communications based on measurements, estimations, or predictions made by the digital twin. Ray tracing performance may be dependent on material properties of a geographic area corresponding to the digital twin. For example, the digital twin may model wireless signaling behavior based on material properties of the physical entities in a three-dimensional (3D) model associated with the geographic area. Such material properties may include a reflection coefficient, a refractive coefficient, a diffraction coefficient, a permittivity, a conductivity, or the like. For instance, a building facade may include (e.g., or be made of) multiple materials (e.g., metal and glass). Accurate material assignment may be essential to successful wireless ray tracing and digital twin creation and use. If material properties are misassigned in a digital twin, then the digital twin may not perform accurately with reference to real life signaling in the corresponding geographic area. However, in some examples of 3D models, a section (e.g., a section of a 3D representation format, such as a point cloud, voxel, neural radiance field, plenoxel, mesh, etc.) of the 3D model may cover (e.g., include) multiple materials. As described herein, a section or a mesh may refer to any such section of a 3D representation (e.g., point cloud, voxel, neural radiance field, plenoxel, mesh, among other examples). Assigning a section (e.g., or entirety) of a 3D model to a single material may result in assignment of material properties that are inaccurate to the actual section covered by the 3D model.

According to techniques described herein, a digital twin server may determine a ratio of different surfaces (e.g., a ratio of the first material to the second material within a given mesh or portion of the 3D model), and create a composite material (e.g., a hypothetical composite material representing a section of a 3D model including multiple materials) which combines the material properties of the multiple (e.g., two or more) detected materials in accordance with the determined ratio. In some examples, the digital twin server may develop a probabilistic distribution-based material model, which may combine ethe properties of individual materials. A digital twin may be generated based on the material properties of the composite material being assigned to the section of the 3D model that includes the different materials.

In some examples, a section (e.g., mesh) of a 3D model may cover two distinct materials, and the digital twin server may divide and subdivide a mesh to ensure that smaller meshes cover a single (e.g., or a majority of one) material. For example, according to techniques described herein, the digital twin server may identify any segments (e.g., portions or meshes) of a 3D model that are larger than a first area threshold. Of these larger meshes, the digital twin server may determine which meshes cover multiple materials. The area of such materials may be calculated for the respective mesh, and if the percentage of area of the material is less than a configured material threshold, the digital twin server may subdivide the mesh. The calculation of percentage area and subdivision may be repeated by the digital twin server until a subdivided mesh does not meet the material threshold (e.g., subject to the area threshold).

Aspects of the disclosure are initially described in the context of wireless communications systems. Aspects of the disclosure are further illustrated by and described with reference to composite material generation schemes, composite material division schemes, apparatus diagrams, system diagrams, and flowcharts that relate to creating composite material properties for digital twin based wireless simulation.

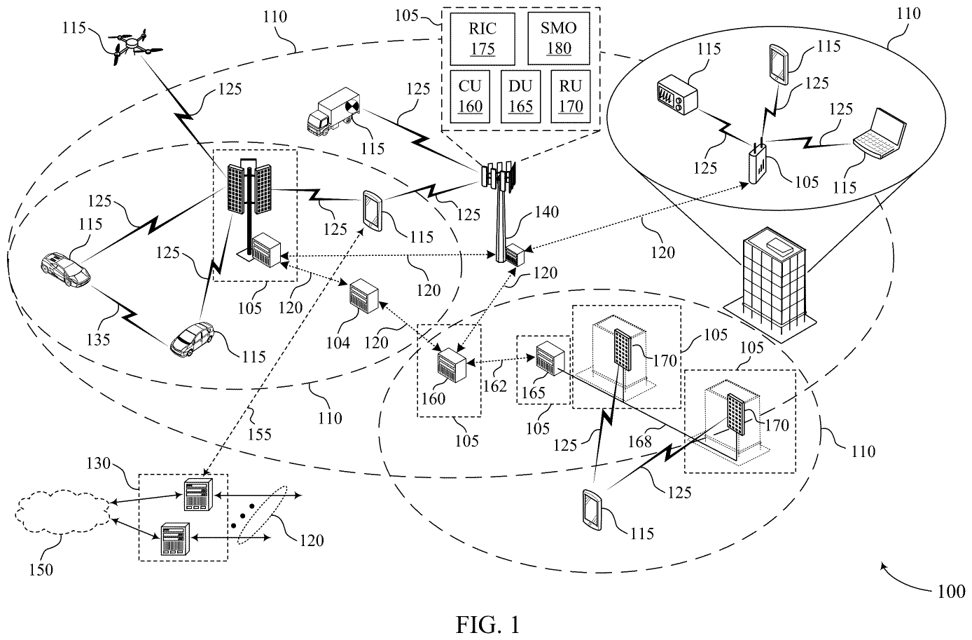

FIG. 1 shows an example of a wireless communications system 100 that supports creating composite material properties for digital twin based wireless simulation in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

For instance, an access network (AN) or RAN may include communications between access nodes (e.g., an IAB donor), IAB node(s) 104, and one or more UEs 115. The IAB donor may facilitate connection between the core network 130 and the AN (e.g., via a wired or wireless connection to the core network 130). That is, an IAB donor may refer to a RAN node with a wired or wireless connection to the core network 130. The IAB donor may include one or more of a CU 160, a DU 165, and an RU 170, in which case the CU 160 may communicate with the core network 130 via an interface (e.g., a backhaul link). The IAB donor and IAB node(s) 104 may communicate via an F1 interface according to a protocol that defines signaling messages (e.g., an F1 AP protocol). Additionally, or alternatively, the CU 160 may communicate with the core network 130 via an interface, which may be an example of a portion of a backhaul link, and may communicate with other CUs (e.g., including a CU 160 associated with an alternative IAB donor) via an Xn-C interface, which may be an example of another portion of a backhaul link.

IAB node(s) 104 may refer to RAN nodes that provide IAB functionality (e.g., access for UEs 115, wireless self-backhauling capabilities). A DU 165 may act as a distributed scheduling node towards child nodes associated with the IAB node(s) 104, and the IAB-MT may act as a scheduled node towards parent nodes associated with IAB node(s) 104. That is, an IAB donor may be referred to as a parent node in communication with one or more child nodes (e.g., an IAB donor may relay transmissions for UEs through other IAB node(s) 104). Additionally, or alternatively, IAB node(s) 104 may also be referred to as parent nodes or child nodes to other IAB node(s) 104, depending on the relay chain or configuration of the AN. The IAB-MT entity of IAB node(s) 104 may provide a Uu interface for a child IAB node (e.g., the IAB node(s) 104) to receive signaling from a parent IAB node (e.g., the IAB node(s) 104), and a DU interface (e.g., a DU 165) may provide a Uu interface for a parent IAB node to signal to a child IAB node or UE 115.

For example, IAB node(s) 104 may be referred to as parent nodes that support communications for child IAB nodes, or may be referred to as child IAB nodes associated with IAB donors, or both. An IAB donor may include a CU 160 with a wired or wireless connection (e.g., backhaul communication link(s) 120) to the core network 130 and may act as a parent node to IAB node(s) 104. For example, the DU 165 of an IAB donor may relay transmissions to UEs 115 through IAB node(s) 104, or may directly signal transmissions to a UE 115, or both. The CU 160 of the IAB donor may signal communication link establishment via an F1 interface to IAB node(s) 104, and the IAB node(s) 104 may schedule transmissions (e.g., transmissions to the UEs 115 relayed from the IAB donor) through one or more DUs (e.g., DUs 165). That is, data may be relayed to and from IAB node(s) 104 via signaling via an NR Uu interface to MT of IAB node(s) 104 (e.g., other IAB node(s)). Communications with IAB node(s) 104 may be scheduled by a DU 165 of the IAB donor or of IAB node(s) 104.

In the case of the techniques described herein applied in the context of a disaggregated RAN architecture, one or more components of the disaggregated RAN architecture may be configured to support creating composite material properties for digital twin based wireless simulation as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

In some examples, such as in a carrier aggregation configuration, a carrier may have acquisition signaling or control signaling that coordinates operations for other carriers. A carrier may be associated with a frequency channel (e.g., an evolved universal mobile telecommunication system terrestrial radio access (E-UTRA) absolute RF channel number (EARFCN)) and may be identified according to a channel raster for discovery by the UEs 115. A carrier may be operated in a standalone mode, in which case initial acquisition and connection may be conducted by the UEs 115 via the carrier, or the carrier may be operated in a non-standalone mode, in which case a connection is anchored using a different carrier (e.g., of the same or a different RAT).

The communication link(s) 125 of the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some examples, the carrier bandwidth may be referred to as a “system bandwidth” of the carrier or the wireless communications system 100. For example, the carrier bandwidth may be one of a set of bandwidths for carriers of a particular RAT (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some examples, the wireless communications system 100 may include network entities 105 or UEs 115 that support concurrent communications using carriers associated with multiple carrier bandwidths. In some examples, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

One or more numerologies for a carrier may be supported, and a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

A network entity 105 may provide communication coverage via one or more cells, for example a macro cell, a small cell, a hot spot, or other types of cells, or any combination thereof. The term “cell” may refer to a logical communication entity used for communication with a network entity 105 (e.g., using a carrier) and may be associated with an identifier for distinguishing neighboring cells (e.g., a physical cell identifier (PCID), a virtual cell identifier (VCID)). In some examples, a cell also may refer to a coverage area 110 or a portion of a coverage area 110 (e.g., a sector) over which the logical communication entity operates. Such cells may range from smaller areas (e.g., a structure, a subset of structure) to larger areas depending on various factors such as the capabilities of the network entity 105. For example, a cell may be or include a building, a subset of a building, or exterior spaces between or overlapping with coverage areas 110, among other examples.

A macro cell generally covers a relatively large geographic area (e.g., several kilometers in radius) and may allow unrestricted access by the UEs 115 with service subscriptions with the network provider supporting the macro cell. A small cell may be associated with a network entity 105 operating with lower power (e.g., a base station 140 operating with lower power) relative to a macro cell, and a small cell may operate using the same or different (e.g., licensed, unlicensed) frequency bands as macro cells. Small cells may provide unrestricted access to the UEs 115 with service subscriptions with the network provider or may provide restricted access to the UEs 115 having an association with the small cell (e.g., the UEs 115 in a closed subscriber group (CSG), the UEs 115 associated with users in a home or office). A network entity 105 may support one or more cells and may also support communications via the one or more cells using one or multiple component carriers.

In some examples, a carrier may support multiple cells, and different cells may be configured according to different protocol types (e.g., MTC, narrowband IoT (NB-IoT), enhanced mobile broadband (eMBB)) that may provide access for different types of devices.

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may support synchronous or asynchronous operation. For synchronous operation, network entities 105 (e.g., base stations 140) may have similar frame timings, and transmissions from different network entities (e.g., different ones of the network entities 105) may be approximately aligned in time. For asynchronous operation, network entities 105 may have different frame timings, and transmissions from different network entities (e.g., different ones of network entities 105) may, in some examples, not be aligned in time. The techniques described herein may be used for either synchronous or asynchronous operations.

Some UEs 115, such as MTC or IoT devices, may be relatively low cost or low complexity devices and may provide for automated communication between machines (e.g., via Machine-to-Machine (M2M) communication). M2M communication or MTC may refer to data communication technologies that allow devices to communicate with one another or a network entity 105 (e.g., a base station 140) without human intervention. In some examples, M2M communication or MTC may include communications from devices that integrate sensors or meters to measure or capture information and relay such information to a central server or application program that uses the information or presents the information to humans interacting with the application program. Some UEs 115 may be designed to collect information or enable automated behavior of machines or other devices. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging.

Some UEs 115 may be configured to employ operating modes that reduce power consumption, such as half-duplex communications (e.g., a mode that supports one-way communication via transmission or reception, but not transmission and reception concurrently). In some examples, half-duplex communications may be performed at a reduced peak rate. Other power conservation techniques for the UEs 115 may include entering a power saving deep sleep mode when not engaging in active communications, operating using a limited bandwidth (e.g., according to narrowband communications), or a combination of these techniques. For example, some UEs 115 may be configured for operation using a narrowband protocol type that is associated with a defined portion or range (e.g., set of subcarriers or resource blocks (RBs)) within a carrier, within a guard-band of a carrier, or outside of a carrier.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHz, also known as the centimeter band, or using an extremely high frequency (EHF) region of the spectrum (e.g., from 30 GHz to 300 GHz), also known as the millimeter band. In some examples, the wireless communications system 100 may support millimeter wave (mmW) communications between the UEs 115 and the network entities 105 (e.g., base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

The network entities 105 or the UEs 115 may use MIMO communications to exploit multipath signal propagation and increase spectral efficiency by transmitting or receiving multiple signals via different spatial layers. Such techniques may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream and may carry information associated with the same data stream (e.g., the same codeword) or different data streams (e.g., different codewords). Different spatial layers may be associated with different antenna ports used for channel measurement and reporting. MIMO techniques include single-user MIMO (SU-MIMO), for which multiple spatial layers are transmitted to the same receiving device, and multiple-user MIMO (MU-MIMO), for which multiple spatial layers are transmitted to multiple devices.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by a transmitting device (e.g., a network entity 105 or a UE 115) along a single beam direction (e.g., a direction associated with the receiving device, such as another network entity 105 or UE 115). In some examples, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some examples, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a transmitting device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

The wireless communications system 100 may be located within a geographic area and, in some cases, a network operator, controller, provider, or planner/developer may create and use a digital twin associated with the geographic area to help make decisions, predictions, or estimations associated with the wireless communications system 100. The network operator, controller, provider, or planner/developer may use the digital twin to model a physical environment in a virtual environment (e.g., a virtual world) and, instead of or in addition to performing measurements or tests within the physical environment, may perform measurements or tests using the model of the physical environment. In other words, a digital twin may be a model of a real-world environment in a virtual world. A digital twin may run any quantity of simulations to study one or multiple processes. A digital twin may have access to near real-time data, such that digital twins may be designed around a two-way flow of information including real-world sensors/measurements (input to a digital twin creation entity) and simulation results (output from the digital twin creation entity).

A digital twin creation entity may generate a digital twin based on a three-dimensional model of a geographic area. Using wireless simulation, one or more transmitters and one or more receivers may be placed within the three-dimensional model and RF paths between the one or more transmitters and the one or more receivers may be raytraced to generate data, with such data being usable to perform studies to predict, estimate, or otherwise determine one or more metrics associated with wireless communications within the geographic area. A network operator, controller, provider, or planner/developer may use such data and/or metrics to make decisions associated with a real-world version of the wireless communications system 100, as such data and/or metrics may approximate actual data and/or metrics that might have been obtained if measurements or tests within the physical environment were performed. In other words, a digital twin associated with a geographic area including the wireless communications system 100 may leverage or otherwise involve wireless simulation (e.g., such as wireless raytracing, artificial intelligence (AI) models, machine learning (ML) models, or the like) to simulate or emulate a performance of the wireless communications system 100.

Wireless communications systems may be modeled by digital twins, increasing the effectiveness and efficiency of wireless communications based on measurements, estimations, or predictions made by the digital twin. Ray tracing performance may be dependent on material properties of a geographic area corresponding to the digital twin. For example, the digital twin may model wireless signaling behavior based on material properties of the physical entities in a three-dimensional (3D) model associated with the geographic area. Such material properties may include a reflection coefficient, a refractive coefficient, a diffraction coefficient, a permittivity, a conductivity, or the like. For instance, a building facade may include (e.g., or be made of) multiple materials (e.g., metal and glass). Accurate material assignment may be essential to successful wireless ray tracing and digital twin creation and use. If material properties are misassigned in a digital twin, then the digital twin may not perform accurately with reference to real life signaling in the corresponding geographic area. However, in some examples of 3D models, a section (e.g., such as a mesh) of the 3D model may cover (e.g., include) multiple materials. Assigning a section (e.g., or entirety) of a 3D model to a single material may result in assignment of material properties that are inaccurate to the actual section covered by the 3D model.

According to techniques described herein, a digital twin server may determine a ratio of different surfaces (e.g., a ratio of the first material to the second material within a given mesh or portion of the 3D model), and create a composite material which combines the material properties of the multiple (e.g., two or more) detected materials) in accordance with the determined ratio. In some examples, the digital twin server may develop a probabilistic distribution-based material model, which may combine ethe properties of individual materials. A digital twin may be generated based on the material properties of the composite material being assigned to the section of the 3D model that includes the different materials.

In some examples, a section (e.g., mesh) of a 3D model may cover two distinct materials, and the digital twin server may divide and subdivide a mesh to ensure that smaller meshes cover a single (e.g., or a majority of one) material. For example, according to techniques described herein, the digital twin server may identify any segments (e.g., portions or meshes) of a 3D model that are larger than a first area threshold. Of these larger meshes, the digital twin server may determine which meshes cover multiple materials. The area of such materials may be calculated for the respective mesh, and if the percentage of area of the material is less than a configured material threshold, the digital twin server may subdivide the mesh. The calculation of percentage area and subdivision may be repeated by the digital twin server until a subdivided mesh does not meet the material threshold (e.g., subject to the area threshold).

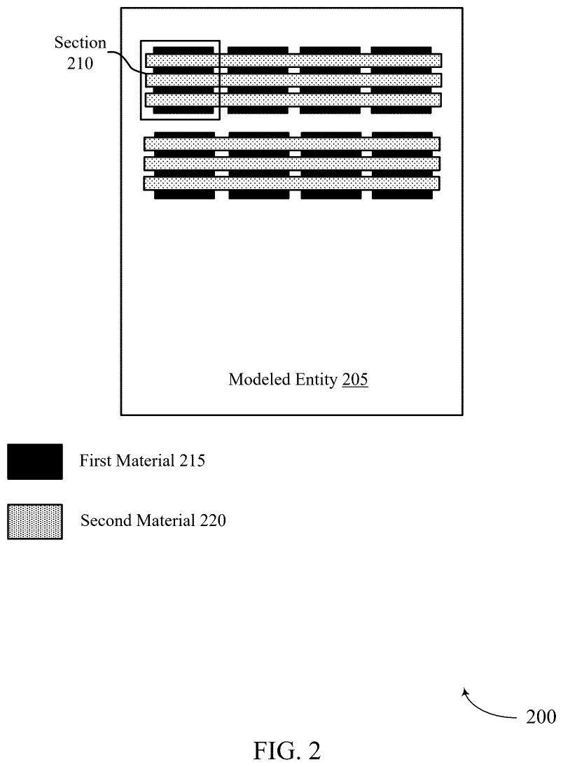

FIG. 2 shows an example of a composite material generation scheme 200 that supports creating composite material properties for digital twin based wireless simulation in accordance with one or more aspects of the present disclosure. The composite material generation scheme may implement, or be implemented by, aspects of the wireless communications system 100. For example, a digital twin creation entity (e.g., which may be an example of a digital twin server, an aspect of the core network 130, or may communicate with or be an example of a UE 115 or a network entity 105) may perform aspects of the composite material generation scheme.

Wireless ray tracing performance (e.g., in digital twin creation scenarios) may be dependent on material properties of a geographic area. For example, the digital twin may model wireless signaling behavior based on transmitters and receivers, and ray tracing based on material properties of the physical entities in a three-dimensional (3D) model associated with the geographic area. Such material properties may include a reflection coefficient, a refractive coefficient, a diffraction coefficient, a permittivity, a conductivity, or the like. For instance, a modeled entity 205 (e.g., such as a building or other physical structure or object) may include (e.g., or be made of) multiple materials. For instance, a tree in a geographic area may include leaves and branches, each of which behave differently in the case of wireless signaling. Similarly, a building may include a first material 215 (e.g., glass) and a second material 220 (e.g., metal).

Accurate material assignment may be essential to successful wireless ray tracing and digital twin creation and use. If material properties are misassigned in a digital twin, then the digital twin may not perform accurately with reference to real life signaling in the corresponding geographic area.

For a 3D model (e.g., generated by one or more map sources, or the like), the 3D model or a resulting digital twin may include multiple 3D representation formats (e.g., meshes, point clouds, voxels, neural radiance fields, octrees, etc.). In some examples, such 3D representation formats may cover (e.g., include) multiple materials. As described herein, meshes may refer to subdivision of any 3D representation formats.

In some examples, a modeled entity 205 (e.g., a building) may include multiple materials, such as a fist material (e.g., glass), and a second material 220 (e.g., metal). Each material may correspond to its own properties. To generate the digital twin of the geographic area including the modeled entity 205, the digital twin server may make a determination as to which properties to assign to one or more portions of the modeled entity 205 that include both the first material 215 and the second material 220. Assigning the façade of the building to metal properties may be incorrect, because the glass behind the metal slats would then be modeled as medal (e.g., which will not accurately reflect the behavior of glass in the real world.). Similarly, assigning the façade to glass may be incorrect, as the metal slats in front of the glass would be modeled as glass (e.g., which would also fail to accurately reflect the behavior of the metal slats in the real world). Techniques described herein support generation of a composite material to apply to portions (e.g., or the entirety of) meshes the cover multiple materials. Such composite materials may reflect a generated set of materials that reflects the behavior of the multiple behaviors within the single mesh (e.g., or multiple meshes).

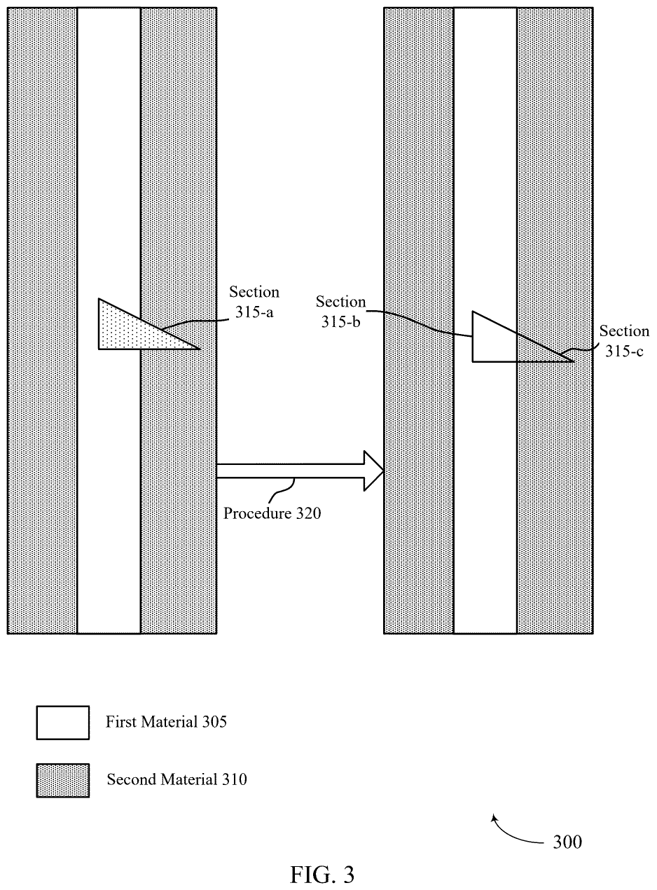

In some examples, various map sources (e.g., or other sources of 3D models) may include 3D maps or models of geographical areas represented by colored meshes. For accurate wireless simulation, each mesh may be represented as a single material. Representation of a single material for a mesh may be difficult if the mesh boundaries span different material types (e.g., as illustrated with reference to FIG. 2 and FIG. 3).

The digital twin server may perform techniques to generate a digital twin (e.g., such as a vision-based flow for digital twin creation). The digital twin may detect overlapping surfaces (e.g., representing multiple materials within a given mesh or portion of a 3D model). According to techniques described herein, the digital twin server may determine a ratio of different surfaces (e.g., a ratio of the first material 215 to the second material 220 within a given mesh or portion of the 3D model), and create a composite material which combines the material properties of the multiple (e.g., two or more) detected materials) in accordance with the determined ratio. In some examples, the digital twin server may develop a probabilistic distribution-based material model, which may combine ethe properties of individual materials.

For instance, the digital twin server may compute a ratio of glass to metal in a section 210 (e.g., a mesh) of the modeled entity 205 (e.g., a façade of a building). The digital twin server may compute a composite material by combining the material properties of the glass and the metal. The digital twin server may assign the composite material properties to the section 210 based on the ratio. In some examples, the digital twin server may utilize an artificial intelligence (AI) or machine learning (ML) model to create the composite material properties. In some examples, the digital twin server may utilize a database of composite materials using real life measurements (e.g., made by the digital twin server, or received from one or more devices such as a UE 115 or a network entity 105 or another server, or the like) or historical data stored at the digital twin server. The digital twin server may thus retrieve the measurement information for any given material (e.g., or composite materials previously used or calculated) from the database. In some examples, such techniques may include incorporating material properties of objects inside of a building or outside of a building. For example, the digital twin server may generate a composite material for a section 210 that includes a metal wall inside of a building with a glass façade (e.g., even though the metal wall is inside the building, the metal wall may have significant radio frequency reflections in addition to or in combination with the glass wall of the building).

Generating composite materials may depend on a location of a transmitter and a receiver. For example, if a transmitter and receiver are far away from a reflector (e.g., the front of a building such as the modeled entity 205), then the overlapping materials may be modeled as a composite metal (e.g. for increased accuracy due to the location of the transmitter or receiver). If the transmitter and receiver are close to the reflector, then the model entity may be modeled with the fine structure, and materials may be assigned at a finer resolution (e.g. smaller sections 210 may be defined and may be more specific to individual materials).

Having generated the composite material, and assigned the composite material to the section 210, the digital twin server may generate a digital twin (e.g. or update a digital twin) based on the assignment. Wireless ray tracing may be improved based on the composite material applied to one or more sections 210 (e.g., or to the entirety of a section 210 or portion of a 3D model, or to an entire 3D model). Such digital twins based on composite materials (e.g., and accurate material properties) may support better quality data.

Techniques described herein may be utilized in generation of digital twins, wireless ray tracing, gaming systems, mapping systems, or the like, among other examples.

Similar techniques may be implemented for a section that includes multiple materials that do not overlap (e.g., such as grass and a sidewalk within a given mesh). However, in some examples (e.g., as described with reference to FIG. 3), the digital twin server may divide and subdivide a given mesh to isolate different materials within different sub-meshes or subsections.

FIG. 3 shows an example of a composite material division scheme 300 that supports creating composite material properties for digital twin based wireless simulation in accordance with one or more aspects of the present disclosure. The composite material division scheme may implement, or be implemented by, aspects of the wireless communications system 100 or the composite material generation scheme 200. For example, a digital twin creation entity (e.g., which may be an example of a digital twin server, an aspect of the core network 130, or may communicate with or be an example of a UE 115 or a network entity 105) may perform aspects of the composite material division scheme.

In some examples, a digital twin server may utilize one or more map sources or other 3D models to generate a 3D model, and a digital twin may be based on one or more such 3D models. A given 3D model or scene may include multiple sections 315. As described herein, a section 315 or a mesh may refer to any section of a 3D representation (e.g., point cloud, voxel, neural radiance field, plenoxel, mesh, among other examples). Of multiple sections 315 (e.g., meshes) within a scene (e.g., of a 3D model, a digital twin, a map source, or the like), some meshes may exceed a threshold size (e.g., a minimum threshold, which may be referred to as an AreaThreshold). For instance, a scene or a 3D model may include a first mesh (e.g., a section 315-a), which covers a first material 305 (e.g., a sidewalk) and a second material 310 (e.g., grass and foliage). The digital twin server may find multiple (e.g. all) meshes that are greater than the AreaThreshold. From these multiple meshes, the digital twin server may detect or otherwise determine one or more meshes (e.g., sections 315) that cover multiple materials (e.g., the section 315-a (e.g., mesh) covers grass and sidewalk). The digital twin server may calculate a percentage (e.g., or ratio) of are of each material within the mesh. If the percentage of area of a first material (e.g., the material having the greatest area in the mesh) is less than a configured threshold (e.g., a MaterialThreshold), then the digital twin server may subdivide the mesh (e.g., may subdivide the section 315-a using a procedure 320). For example, the percentage of the sidewalk (e.g., the first material 305) covered by the mesh (e.g., the section 315-a) may be greater than the percentage of the grass (e.g., the second material 310) covered by the mesh, and the percentage of the sidewalk covered by the mesh may be less than a MaterialThreshold (e.g., the MaterialThreshold may be different for each material, and may be calculated or stored in a database, among other examples). The subdivision (e.g., the procedure 320) may be mathematical (e.g., a division of the mesh triangle into two parts, or more parts, which may be equal or based on the materials, among other examples). The subdivision may be a computer vision (CV) based and may use parameters like object boundaries (e.g., walkway vs. grass), color, texture, etc.

As a result of the subdivision, the mesh may be divided into a first portion (e.g., a first new mesh or a first section 315-b) covering the first material 305 (e.g., sidewalk) and a second portion (e.g., a second new mesh or a second section 315-c) covering the second material 310 (e.g., grass and foliage).

In some examples, the digital twin server may repeat steps (e.g., including calculating a percentage of area of each material in a sub-mesh and if the percentage area of the material with the greatest area in the sub-mesh is less than a configured MaterialThreshold, subdividing the sub-mesh into two or more additional sub-meshes). The digital twin server may continue to divide and subdivide for each subdivided mesh if a subdivided mesh does not meet the material threshold criteria, subject to the AreaThreshold limit. For example, if a material within the subdivided mesh no longer covers a percentage of area that is less than the Material Threshold, or if a size of the subdivided mesh is smaller than the AreaThreshold, or both, then the digital twin server may refrain from further subdividing the subdivided mesh.

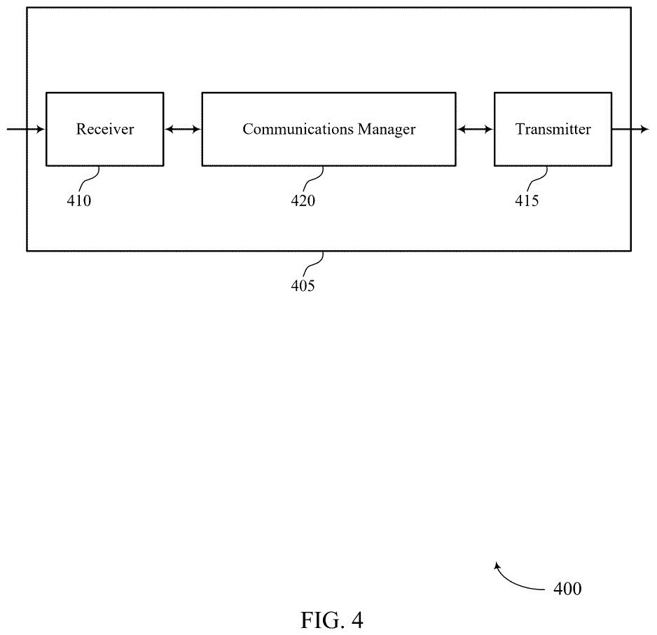

FIG. 4 shows a block diagram 400 of a device 405 that supports creating composite material properties for digital twin based wireless simulation in accordance with one or more aspects of the present disclosure. The device 405 may be an example of aspects of a digital twin server, which may be or may be in communication with a UE 115 or a network entity 105 as described herein. The device 405 may include a receiver 410, a transmitter 415, and a digital twin creation entity 420. The device 405, or one or more components of the device 405 (e.g., the receiver 410, the transmitter 415, the digital twin creation entity 420), may include at least one processor, which may be coupled with at least one memory, to, individually or collectively, support or enable the described techniques. Each of these components may be in communication with one another (e.g., via one or more buses).

The receiver 410 may provide a means for receiving information such as packets, user data, control information, or any combination thereof associated with various information channels (e.g., control channels, data channels, information channels related to creating composite material properties for digital twin based wireless simulation). Information may be passed on to other components of the device 405. The receiver 410 may utilize a single antenna or a set of multiple antennas.

The transmitter 415 may provide a means for transmitting signals generated by other components of the device 405. For example, the transmitter 415 may transmit information such as packets, user data, control information, or any combination thereof associated with various information channels (e.g., control channels, data channels, information channels related to creating composite material properties for digital twin based wireless simulation). In some examples, the transmitter 415 may be co-located with a receiver 410 in a transceiver module. The transmitter 415 may utilize a single antenna or a set of multiple antennas.

The digital twin creation entity 420, the receiver 410, the transmitter 415, or various combinations or components thereof may be examples of means for performing various aspects of creating composite material properties for digital twin based wireless simulation as described herein. For example, the digital twin creation entity 420, the receiver 410, the transmitter 415, or various combinations or components thereof may be capable of performing one or more of the functions described herein.

In some examples, the digital twin creation entity 420, the receiver 410, the transmitter 415, or various combinations or components thereof may be implemented in hardware (e.g., in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the digital twin creation entity 420, the receiver 410, the transmitter 415, or various combinations or components thereof may be implemented in code (e.g., as communications management software or firmware) executed by at least one processor (e.g., referred to as a processor-executable code). If implemented in code executed by at least one processor, the functions of the digital twin creation entity 420, the receiver 410, the transmitter 415, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the digital twin creation entity 420 may be configured to perform various operations (e.g., receiving, obtaining, monitoring, outputting, transmitting) using or otherwise in cooperation with the receiver 410, the transmitter 415, or both. For example, the digital twin creation entity 420 may receive information from the receiver 410, send information to the transmitter 415, or be integrated in combination with the receiver 410, the transmitter 415, or both to obtain information, output information, or perform various other operations as described herein.

The digital twin creation entity 420 may support digital twin creation in accordance with examples as disclosed herein. For example, the digital twin creation entity 420 is capable of, configured to, or operable to support a means for obtaining a three-dimensional model of a geographic area, where at least a first portion of the three-dimensional model includes a first material corresponding to a first set of properties and a second material corresponding to a second set of properties. The digital twin creation entity 420 is capable of, configured to, or operable to support a means for computing a ratio between the first material and the second material in at least the first portion of the three-dimensional model. The digital twin creation entity 420 is capable of, configured to, or operable to support a means for generating a composite material corresponding to a third set of properties by combining the first set of properties and the second set of properties in accordance with the ratio. The digital twin creation entity 420 is capable of, configured to, or operable to support a means for outputting a digital twin associated with the geographic area based on the composite material and the third set of properties.

Additionally, or alternatively, the digital twin creation entity 420 may support digital twin creation in accordance with examples as disclosed herein. For example, the digital twin creation entity 420 is capable of, configured to, or operable to support a means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The digital twin creation entity 420 is capable of, configured to, or operable to support a means for calculating a percentage of the first material in the first mesh. The digital twin creation entity 420 is capable of, configured to, or operable to support a means for subdividing the first mesh into a first portion corresponding to the first material and the second material and a second portion corresponding to the second material based on the percentage of the first material in the first mesh satisfying a second threshold value. The digital twin creation entity 420 is capable of, configured to, or operable to support a means for outputting a digital twin associated with the geographic area based on the first set of properties corresponding to the first portion of the first mesh and the second set of properties corresponding to the second portion of the first mesh.

By including or configuring the digital twin creation entity 420 in accordance with examples as described herein, the device 405 (e.g., at least one processor controlling or otherwise coupled with the receiver 410, the transmitter 415, the digital twin creation entity 420, or a combination thereof) may support techniques for digital twin generation and material assignments resulting in more effective digital twins, more accurate ray tracing, more effective and efficient wireless communications, improved throughput, and improved user experience.

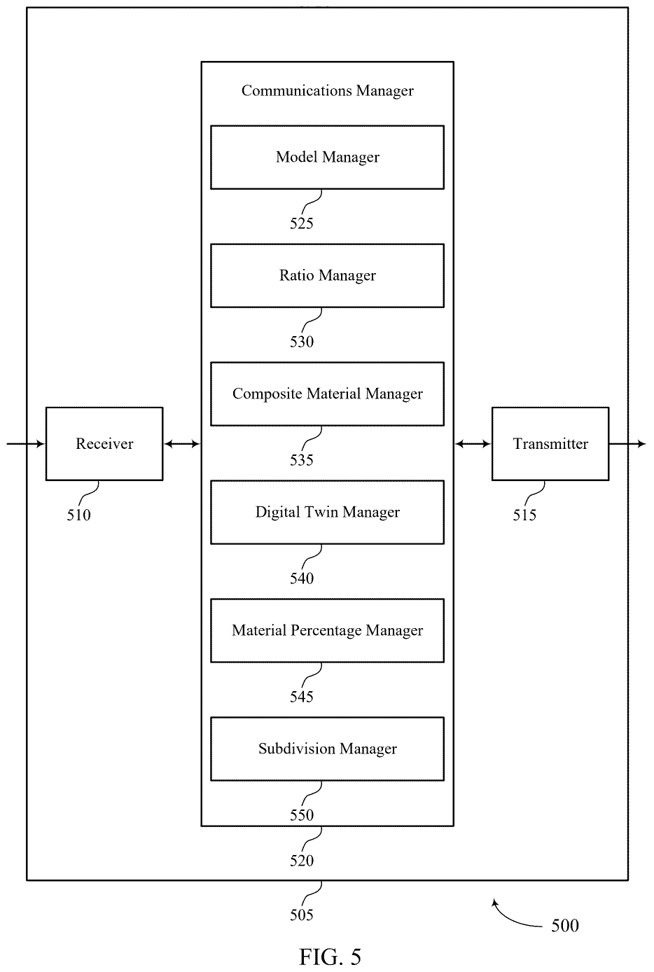

FIG. 5 shows a block diagram 500 of a device 505 that supports creating composite material properties for digital twin based wireless simulation in accordance with one or more aspects of the present disclosure. The device 505 may be an example of aspects of a device 405, a digital twin server as described herein. The device 505 may include a receiver 510, a transmitter 515, and a digital twin creation entity 520. The device 505, or one of more components of the device 505 (e.g., the receiver 510, the transmitter 515, the digital twin creation entity 520), may include at least one processor, which may be coupled with at least one memory, to support the described techniques. Each of these components may be in communication with one another (e.g., via one or more buses).

The receiver 510 may provide a means for receiving information such as packets, user data, control information, or any combination thereof associated with various information channels (e.g., control channels, data channels, information channels related to creating composite material properties for digital twin based wireless simulation). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (e.g., control channels, data channels, information channels related to creating composite material properties for digital twin based wireless simulation). In some examples, the transmitter 515 may be co-located with a receiver 510 in a transceiver module. The transmitter 515 may utilize a single antenna or a set of multiple antennas.

The device 505, or various components thereof, may be an example of means for performing various aspects of creating composite material properties for digital twin based wireless simulation as described herein. For example, the digital twin creation entity 520 may include a model manager 525, a ratio manager 530, a composite material manager 535, a digital twin manager 540, a material percentage manager 545, a subdivision manager 550, or any combination thereof. The digital twin creation entity 520 may be an example of aspects of a digital twin creation entity 420 as described herein. In some examples, the digital twin creation entity 520, or various components thereof, may be configured to perform various operations (e.g., receiving, obtaining, monitoring, outputting, transmitting) using or otherwise in cooperation with the receiver 510, the transmitter 515, or both. For example, the digital twin creation entity 520 may receive information from the receiver 510, send information to the transmitter 515, or be integrated in combination with the receiver 510, the transmitter 515, or both to obtain information, output information, or perform various other operations as described herein.

The digital twin creation entity 520 may support digital twin creation in accordance with examples as disclosed herein. The model manager 525 is capable of, configured to, or operable to support a means for obtaining a three-dimensional model of a geographic area, where at least a first portion of the three-dimensional model includes a first material corresponding to a first set of properties and a second material corresponding to a second set of properties. The ratio manager 530 is capable of, configured to, or operable to support a means for computing a ratio between the first material and the second material in at least the first portion of the three-dimensional model. The composite material manager 535 is capable of, configured to, or operable to support a means for generating a composite material corresponding to a third set of properties by combining the first set of properties and the second set of properties in accordance with the ratio. The digital twin manager 540 is capable of, configured to, or operable to support a means for outputting a digital twin associated with the geographic area based on the composite material and the third set of properties.

Additionally, or alternatively, the digital twin creation entity 520 may support digital twin creation in accordance with examples as disclosed herein. The model manager 525 is capable of, configured to, or operable to support a means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The material percentage manager 545 is capable of, configured to, or operable to support a means for calculating a percentage of the first material in the first mesh. The subdivision manager 550 is capable of, configured to, or operable to support a means for subdividing the first mesh into a first portion corresponding to the first material and the second material and a second portion corresponding to the second material based on the percentage of the first material in the first mesh satisfying a second threshold value. The digital twin manager 540 is capable of, configured to, or operable to support a means for outputting a digital twin associated with the geographic area based on the first set of properties corresponding to the first portion of the first mesh and the second set of properties corresponding to the second portion of the first mesh.

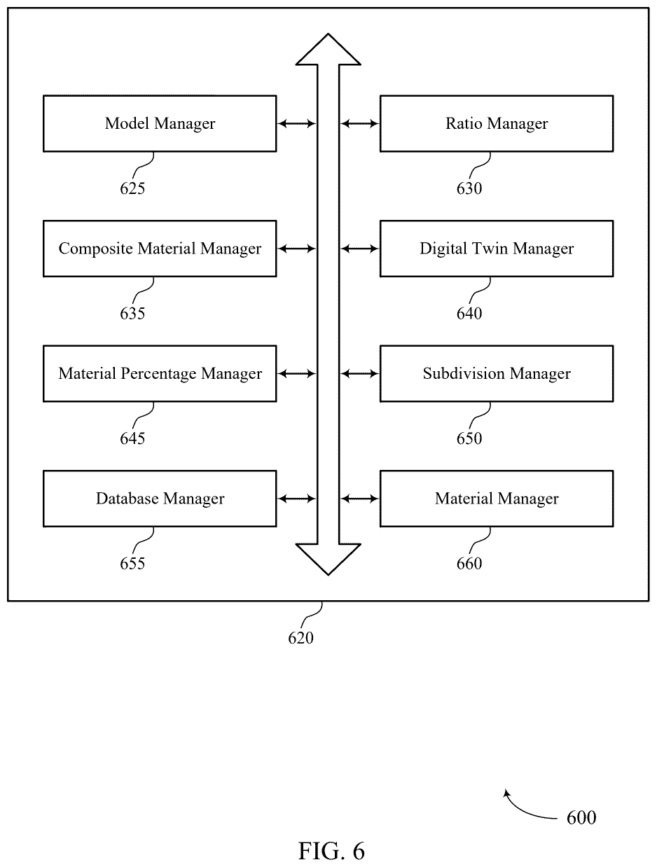

FIG. 6 shows a block diagram 600 of a digital twin creation entity 620 that supports creating composite material properties for digital twin based wireless simulation in accordance with one or more aspects of the present disclosure. The digital twin creation entity 620 may be an example of aspects of a digital twin creation entity 420, a digital twin creation entity 520, or both, as described herein. The digital twin creation entity 620, or various components thereof, may be an example of means for performing various aspects of creating composite material properties for digital twin based wireless simulation as described herein. For example, the digital twin creation entity 620 may include a model manager 625, a ratio manager 630, a composite material manager 635, a digital twin manager 640, a material percentage manager 645, a subdivision manager 650, a database manager 655, a material manager 660, or any combination thereof. Each of these components, or components or subcomponents thereof (e.g., one or more processors, one or more memories), may communicate, directly or indirectly, with one another (e.g., via one or more buses). The communications may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The digital twin creation entity 620 may support digital twin creation in accordance with examples as disclosed herein. The model manager 625 is capable of, configured to, or operable to support a means for obtaining a three-dimensional model of a geographic area, where at least a first portion of the three-dimensional model includes a first material corresponding to a first set of properties and a second material corresponding to a second set of properties. The ratio manager 630 is capable of, configured to, or operable to support a means for computing a ratio between the first material and the second material in at least the first portion of the three-dimensional model. The composite material manager 635 is capable of, configured to, or operable to support a means for generating a composite material corresponding to a third set of properties by combining the first set of properties and the second set of properties in accordance with the ratio. The digital twin manager 640 is capable of, configured to, or operable to support a means for outputting a digital twin associated with the geographic area based on the composite material and the third set of properties.

In some examples, the composite material manager 635 is capable of, configured to, or operable to support a means for assigning the composite material corresponding to the third set of properties to at least the first portion of the three-dimensional model, where outputting the digital twin is based on the assigning.

In some examples, to support computing the composite material, the composite material manager 635 is capable of, configured to, or operable to support a means for generating a model of the composite material corresponding to the third set of properties via a machine learning model.

In some examples, the database manager 655 is capable of, configured to, or operable to support a means for obtaining the first set of properties corresponding to the first material and the second set of properties for responding to the second material from a database, where generating the composite material corresponding to the third set of properties is based on obtaining the first set of properties and the second set of properties from the database.

In some examples, the database manager 655 is capable of, configured to, or operable to support a means for obtaining a first set of multiple measurements corresponding to the first material, the first set of properties based on the first set of multiple measurements. In some examples, the database manager 655 is capable of, configured to, or operable to support a means for obtaining a second set of multiple measurements corresponding to the second material, the second set of properties based on the second set of multiple measurements. In some examples, the database manager 655 is capable of, configured to, or operable to support a means for storing the first set of properties and the second set of properties in the database based on obtaining the first set of multiple measurements and the second set of multiple measurements.

In some examples, the first material and the second material are internal or external to one or more structures of the three-dimensional model.

Additionally, or alternatively, the digital twin creation entity 620 may support digital twin creation in accordance with examples as disclosed herein. In some examples, the model manager 625 is capable of, configured to, or operable to support a means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The material percentage manager 645 is capable of, configured to, or operable to support a means for calculating a percentage of the first material in the first mesh. The subdivision manager 650 is capable of, configured to, or operable to support a means for subdividing the first mesh into a first portion corresponding to the first material and the second material and a second portion corresponding to the second material based on the percentage of the first material in the first mesh satisfying a second threshold value. In some examples, the digital twin manager 640 is capable of, configured to, or operable to support a means for outputting a digital twin associated with the geographic area based on the first set of properties corresponding to the first portion of the first mesh and the second set of properties corresponding to the second portion of the first mesh.

In some examples, the material manager 660 is capable of, configured to, or operable to support a means for assigning the first set of properties to the first portion of the first mesh. In some examples, the material manager 660 is capable of, configured to, or operable to support a means for assigning the second set of properties to the second portion of the first mesh, where the digital twin is based on assigning the first set of properties to the first portion of the first mesh and assigning the second set of properties to the second portion of the first mesh.

In some examples, to support subdividing the first mesh, the subdivision manager 650 is capable of, configured to, or operable to support a means for subdividing the first mesh multiple times until a size of the resulting subdivision of the first mesh fails to satisfy the first threshold, or the percentage of the first material in a resulting subdivision of the first mesh fails to satisfy the second threshold value.

In some examples, to support subdividing the first mesh, the subdivision manager 650 is capable of, configured to, or operable to support a means for subdividing the first mesh based on an object boundary within the first mesh.

In some examples, to support subdividing the first mesh, the subdivision manager 650 is capable of, configured to, or operable to support a means for subdividing the first mesh based on a mathematical division into equal portions.

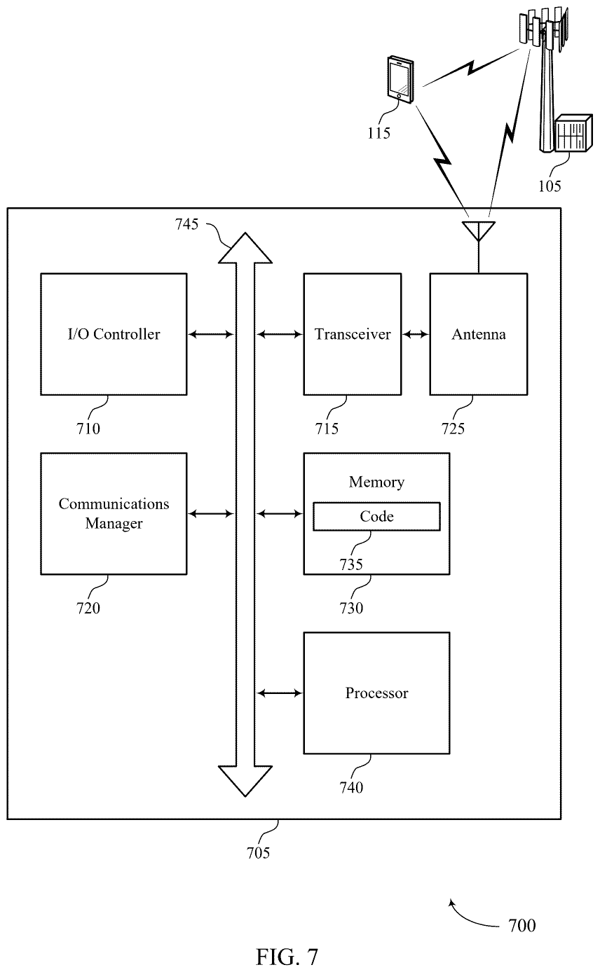

FIG. 7 shows a diagram of a system 700 including a device 705 that supports creating composite material properties for digital twin based wireless simulation in accordance with one or more aspects of the present disclosure. The device 705 may be an example of or include components of a device 405, a device 505, or a digital twin server as described herein. The device 705 may communicate (e.g., wirelessly) with one or more other devices (e.g., network entities 105, UEs 115, or a combination thereof). The device 705 may include components for bi-directional voice and data communications including components for transmitting and receiving communications, such as a digital twin creation entity 720, an input/output (I/O) controller, such as an I/O controller 710, a transceiver 715, one or more antennas 725, at least one memory 730, code 735, and at least one processor 740. These components may be in electronic communication or otherwise coupled (e.g., operatively, communicatively, functionally, electronically, electrically) via one or more buses (e.g., a bus 745).

The I/O controller 710 may manage input and output signals for the device 705. The I/O controller 710 may also manage peripherals not integrated into the device 705. In some cases, the I/O controller 710 may represent a physical connection or port to an external peripheral. In some cases, the I/O controller 710 may utilize an operating system such as iOS®, ANDROID®, MS-DOS®, MS-WINDOWS®, OS/2®, UNIX®, LINUX®, or another known operating system. Additionally, or alternatively, the I/O controller 710 may represent or interact with a modem, a keyboard, a mouse, a touchscreen, or a similar device. In some cases, the I/O controller 710 may be implemented as part of one or more processors, such as the at least one processor 740. In some cases, a user may interact with the device 705 via the I/O controller 710 or via hardware components controlled by the I/O controller 710.

In some cases, the device 705 may include a single antenna. However, in some other cases, the device 705 may have more than one antenna, which may be capable of concurrently transmitting or receiving multiple wireless transmissions. The transceiver 715 may communicate bi-directionally via the one or more antennas 725 using wired or wireless links as described herein. For example, the transceiver 715 may represent a wireless transceiver and may communicate bi-directionally with another wireless transceiver. The transceiver 715 may also include a modem to modulate the packets, to provide the modulated packets to one or more antennas 725 for transmission, and to demodulate packets received from the one or more antennas 725. The transceiver 715, or the transceiver 715 and one or more antennas 725, may be an example of a transmitter 415, a transmitter 515, a receiver 410, a receiver 510, or any combination thereof or component thereof, as described herein.

The at least one memory 730 may include random access memory (RAM) and read-only memory (ROM). The at least one memory 730 may store computer-readable, computer-executable, or processor-executable code, such as the code 735. The code 735 may include instructions that, when executed by the at least one processor 740, cause the device 705 to perform various functions described herein. The code 735 may be stored in a non-transitory computer-readable medium such as system memory or another type of memory. In some cases, the code 735 may not be directly executable by the at least one processor 740 but may cause a computer (e.g., when compiled and executed) to perform functions described herein. In some cases, the at least one memory 730 may include, among other things, a basic I/O system (BIOS) which may control basic hardware or software operation such as the interaction with peripheral components or devices.

The at least one processor 740 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 740 may be configured to operate a memory array using a memory controller. In some other cases, a memory controller may be integrated into the at least one processor 740. The at least one processor 740 may be configured to execute computer-readable instructions stored in a memory (e.g., the at least one memory 730) to cause the device 705 to perform various functions (e.g., functions or tasks supporting creating composite material properties for digital twin based wireless simulation). For example, the device 705 or a component of the device 705 may include at least one processor 740 and at least one memory 730 coupled with or to the at least one processor 740, the at least one processor 740 and the at least one memory 730 configured to perform various functions described herein.

In some examples, the at least one processor 740 may include multiple processors and the at least one memory 730 may include multiple memories. One or more of the multiple processors may be coupled with one or more of the multiple memories, which may, individually or collectively, be configured to perform various functions described herein. In some examples, the at least one processor 740 may be a component of a processing system, which may refer to a system (such as a series) of machines, circuitry (including, for example, one or both of processor circuitry (which may include the at least one processor 740) and memory circuitry (which may include the at least one memory 730)), or components, that receives or obtains inputs and processes the inputs to produce, generate, or obtain a set of outputs. The processing system may be configured to perform one or more of the functions described herein. For example, the at least one processor 740 or a processing system including the at least one processor 740 may be configured to, configurable to, or operable to cause the device 705 to perform one or more of the functions described herein. Further, as described herein, being “configured to,” being “configurable to,” and being “operable to” may be used interchangeably and may be associated with a capability, when executing code 735 (e.g., processor-executable code) stored in the at least one memory 730 or otherwise, to perform one or more of the functions described herein.

The digital twin creation entity 720 may support digital twin creation in accordance with examples as disclosed herein. For example, the digital twin creation entity 720 is capable of, configured to, or operable to support a means for obtaining a three-dimensional model of a geographic area, where at least a first portion of the three-dimensional model includes a first material corresponding to a first set of properties and a second material corresponding to a second set of properties. The digital twin creation entity 720 is capable of, configured to, or operable to support a means for computing a ratio between the first material and the second material in at least the first portion of the three-dimensional model. The digital twin creation entity 720 is capable of, configured to, or operable to support a means for generating a composite material corresponding to a third set of properties by combining the first set of properties and the second set of properties in accordance with the ratio. The digital twin creation entity 720 is capable of, configured to, or operable to support a means for outputting a digital twin associated with the geographic area based on the composite material and the third set of properties.

Additionally, or alternatively, the digital twin creation entity 720 may support digital twin creation in accordance with examples as disclosed herein. For example, the digital twin creation entity 720 is capable of, configured to, or operable to support a means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The digital twin creation entity 720 is capable of, configured to, or operable to support a means for calculating a percentage of the first material in the first mesh. The digital twin creation entity 720 is capable of, configured to, or operable to support a means for subdividing the first mesh into a first portion corresponding to the first material and the second material and a second portion corresponding to the second material based on the percentage of the first material in the first mesh satisfying a second threshold value. The digital twin creation entity 720 is capable of, configured to, or operable to support a means for outputting a digital twin associated with the geographic area based on the first set of properties corresponding to the first portion of the first mesh and the second set of properties corresponding to the second portion of the first mesh.

By including or configuring the digital twin creation entity 720 in accordance with examples as described herein, the device 705 may support techniques for digital twin generation and material assignments resulting in more effective digital twins, more accurate ray tracing, more effective and efficient wireless communications, improved throughput, and improved user experience.

In some examples, the digital twin creation entity 720 may be configured to perform various operations (e.g., receiving, monitoring, transmitting) using or otherwise in cooperation with the transceiver 715, the one or more antennas 725, or any combination thereof. Although the digital twin creation entity 720 is illustrated as a separate component, in some examples, one or more functions described with reference to the digital twin creation entity 720 may be supported by or performed by the at least one processor 740, the at least one memory 730, the code 735, or any combination thereof. For example, the code 735 may include instructions executable by the at least one processor 740 to cause the device 705 to perform various aspects of creating composite material properties for digital twin based wireless simulation as described herein, or the at least one processor 740 and the at least one memory 730 may be otherwise configured to, individually or collectively, perform or support such operations.

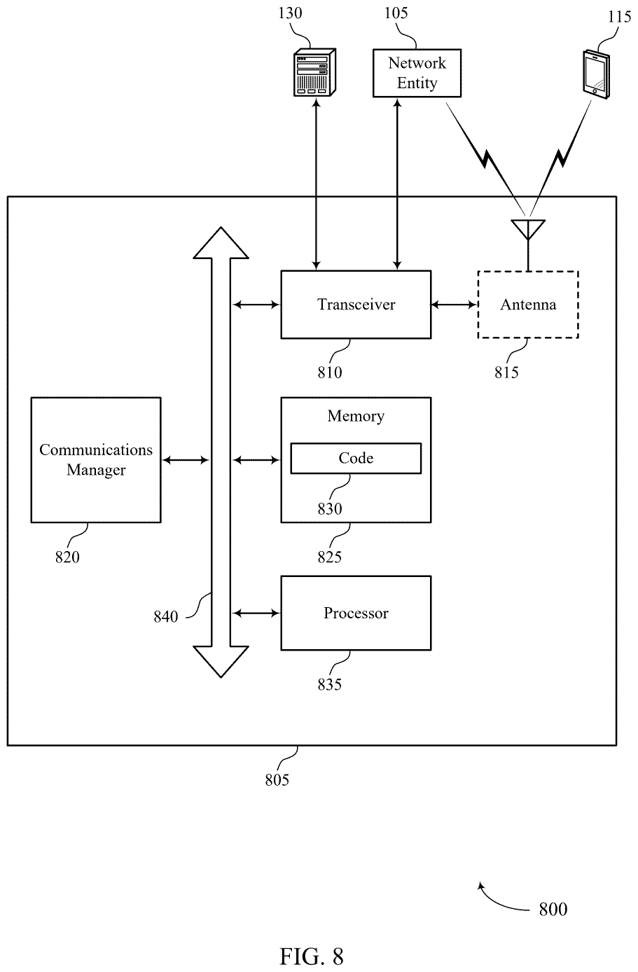

FIG. 8 shows a diagram of a system 800 including a device 805 that supports creating composite material properties for digital twin based wireless simulation in accordance with one or more aspects of the present disclosure. The device 805 may be an example of or include components of a device 405, a device 505, or a digital twin server as described herein. The device 805 may communicate with other network devices or network equipment such as one or more of the network entities 105, UEs 115, or any combination thereof. The communications may include communications over one or more wired interfaces, over one or more wireless interfaces, or any combination thereof. The device 805 may include components that support outputting and obtaining communications, such as a digital twin creation entity 820, a transceiver 810, one or more antennas 815, at least one memory 825, code 830, and at least one processor 835. These components may be in electronic communication or otherwise coupled (e.g., operatively, communicatively, functionally, electronically, electrically) via one or more buses (e.g., a bus 840).

The transceiver 810 may support bi-directional communications via wired links, wireless links, or both as described herein. In some examples, the transceiver 810 may include a wired transceiver and may communicate bi-directionally with another wired transceiver. Additionally, or alternatively, in some examples, the transceiver 810 may include a wireless transceiver and may communicate bi-directionally with another wireless transceiver. In some examples, the device 805 may include one or more antennas 815, which may be capable of transmitting or receiving wireless transmissions (e.g., concurrently). The transceiver 810 may also include a modem to modulate signals, to provide the modulated signals for transmission (e.g., by one or more antennas 815, by a wired transmitter), to receive modulated signals (e.g., from one or more antennas 815, from a wired receiver), and to demodulate signals. In some implementations, the transceiver 810 may include one or more interfaces, such as one or more interfaces coupled with the one or more antennas 815 that are configured to support various receiving or obtaining operations, or one or more interfaces coupled with the one or more antennas 815 that are configured to support various transmitting or outputting operations, or a combination thereof. In some implementations, the transceiver 810 may include or be configured for coupling with one or more processors or one or more memory components that are operable to perform or support operations based on received or obtained information or signals, or to generate information or other signals for transmission or other outputting, or any combination thereof. In some implementations, the transceiver 810, or the transceiver 810 and the one or more antennas 815, or the transceiver 810 and the one or more antennas 815 and one or more processors or one or more memory components (e.g., the at least one processor 835, the at least one memory 825, or both), may be included in a chip or chip assembly that is installed in the device 805. In some examples, the transceiver 810 may be operable to support communications via one or more communications links (e.g., communication link(s) 125, backhaul communication link(s) 120, a midhaul communication link 162, a fronthaul communication link 168).

The at least one memory 825 may include RAM, ROM, or any combination thereof. The at least one memory 825 may store computer-readable, computer-executable, or processor-executable code, such as the code 830. The code 830 may include instructions that, when executed by one or more of the at least one processor 835, cause the device 805 to perform various functions described herein. The code 830 may be stored in a non-transitory computer-readable medium such as system memory or another type of memory. In some cases, the code 830 may not be directly executable by a processor of the at least one processor 835 but may cause a computer (e.g., when compiled and executed) to perform functions described herein. In some cases, the at least one memory 825 may include, among other things, a BIOS which may control basic hardware or software operation such as the interaction with peripheral components or devices. In some examples, the at least one processor 835 may include multiple processors and the at least one memory 825 may include multiple memories. One or more of the multiple processors may be coupled with one or more of the multiple memories which may, individually or collectively, be configured to perform various functions herein (for example, as part of a processing system).

The at least one processor 835 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 835 may be configured to operate a memory array using a memory controller. In some other cases, a memory controller may be integrated into one or more of the at least one processor 835. The at least one processor 835 may be configured to execute computer-readable instructions stored in a memory (e.g., one or more of the at least one memory 825) to cause the device 805 to perform various functions (e.g., functions or tasks supporting creating composite material properties for digital twin based wireless simulation). For example, the device 805 or a component of the device 805 may include at least one processor 835 and at least one memory 825 coupled with one or more of the at least one processor 835, the at least one processor 835 and the at least one memory 825 configured to perform various functions described herein. The at least one processor 835 may be an example of a cloud-computing platform (e.g., one or more physical nodes and supporting software such as operating systems, virtual machines, or container instances) that may host the functions (e.g., by executing code 830) to perform the functions of the device 805. The at least one processor 835 may be any one or more suitable processors capable of executing scripts or instructions of one or more software programs stored in the device 805 (such as within one or more of the at least one memory 825).

In some examples, the at least one processor 835 may include multiple processors and the at least one memory 825 may include multiple memories. One or more of the multiple processors may be coupled with one or more of the multiple memories, which may, individually or collectively, be configured to perform various functions herein. In some examples, the at least one processor 835 may be a component of a processing system, which may refer to a system (such as a series) of machines, circuitry (including, for example, one or both of processor circuitry (which may include the at least one processor 835) and memory circuitry (which may include the at least one memory 825)), or components, that receives or obtains inputs and processes the inputs to produce, generate, or obtain a set of outputs. The processing system may be configured to perform one or more of the functions described herein. For example, the at least one processor 835 or a processing system including the at least one processor 835 may be configured to, configurable to, or operable to cause the device 805 to perform one or more of the functions described herein. Further, as described herein, being “configured to,” being “configurable to,” and being “operable to” may be used interchangeably and may be associated with a capability, when executing code stored in the at least one memory 825 or otherwise, to perform one or more of the functions described herein.

In some examples, a bus 840 may support communications of (e.g., within) a protocol layer of a protocol stack. In some examples, a bus 840 may support communications associated with a logical channel of a protocol stack (e.g., between protocol layers of a protocol stack), which may include communications performed within a component of the device 805, or between different components of the device 805 that may be co-located or located in different locations (e.g., where the device 805 may refer to a system in which one or more of the digital twin creation entity 820, the transceiver 810, the at least one memory 825, the code 830, and the at least one processor 835 may be located in one of the different components or divided between different components).

In some examples, the digital twin creation entity 820 may manage aspects of communications with a core network 130 (e.g., via one or more wired or wireless backhaul links). For example, the digital twin creation entity 820 may manage the transfer of data communications for client devices, such as one or more UEs 115. In some examples, the digital twin creation entity 820 may manage communications with one or more other network entities 105, and may include a controller or scheduler for controlling communications with UEs 115 (e.g., in cooperation with the one or more other network devices). In some examples, the digital twin creation entity 820 may support an X2 interface within an LTE/LTE-A wireless communications network technology to provide communication between network entities 105.

The digital twin creation entity 820 may support digital twin creation in accordance with examples as disclosed herein. For example, the digital twin creation entity 820 is capable of, configured to, or operable to support a means for obtaining a three-dimensional model of a geographic area, where at least a first portion of the three-dimensional model includes a first material corresponding to a first set of properties and a second material corresponding to a second set of properties. The digital twin creation entity 820 is capable of, configured to, or operable to support a means for computing a ratio between the first material and the second material in at least the first portion of the three-dimensional model. The digital twin creation entity 820 is capable of, configured to, or operable to support a means for generating a composite material corresponding to a third set of properties by combining the first set of properties and the second set of properties in accordance with the ratio. The digital twin creation entity 820 is capable of, configured to, or operable to support a means for outputting a digital twin associated with the geographic area based on the composite material and the third set of properties.

Additionally, or alternatively, the digital twin creation entity 820 may support digital twin creation in accordance with examples as disclosed herein. For example, the digital twin creation entity 820 is capable of, configured to, or operable to support a means for obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The digital twin creation entity 820 is capable of, configured to, or operable to support a means for calculating a percentage of the first material in the first mesh. The digital twin creation entity 820 is capable of, configured to, or operable to support a means for subdividing the first mesh into a first portion corresponding to the first material and the second material and a second portion corresponding to the second material based on the percentage of the first material in the first mesh satisfying a second threshold value. The digital twin creation entity 820 is capable of, configured to, or operable to support a means for outputting a digital twin associated with the geographic area based on the first set of properties corresponding to the first portion of the first mesh and the second set of properties corresponding to the second portion of the first mesh.

By including or configuring the digital twin creation entity 820 in accordance with examples as described herein, the device 805 may support techniques for digital twin generation and material assignments resulting in more effective digital twins, more accurate ray tracing, more effective and efficient wireless communications, improved throughput, and improved user experience.

In some examples, the digital twin creation entity 820 may be configured to perform various operations (e.g., receiving, obtaining, monitoring, outputting, transmitting) using or otherwise in cooperation with the transceiver 810, the one or more antennas 815 (e.g., where applicable), or any combination thereof. Although the digital twin creation entity 820 is illustrated as a separate component, in some examples, one or more functions described with reference to the digital twin creation entity 820 may be supported by or performed by the transceiver 810, one or more of the at least one processor 835, one or more of the at least one memory 825, the code 830, or any combination thereof (for example, by a processing system including at least a portion of the at least one processor 835, the at least one memory 825, the code 830, or any combination thereof). For example, the code 830 may include instructions executable by one or more of the at least one processor 835 to cause the device 805 to perform various aspects of creating composite material properties for digital twin based wireless simulation as described herein, or the at least one processor 835 and the at least one memory 825 may be otherwise configured to, individually or collectively, perform or support such operations.

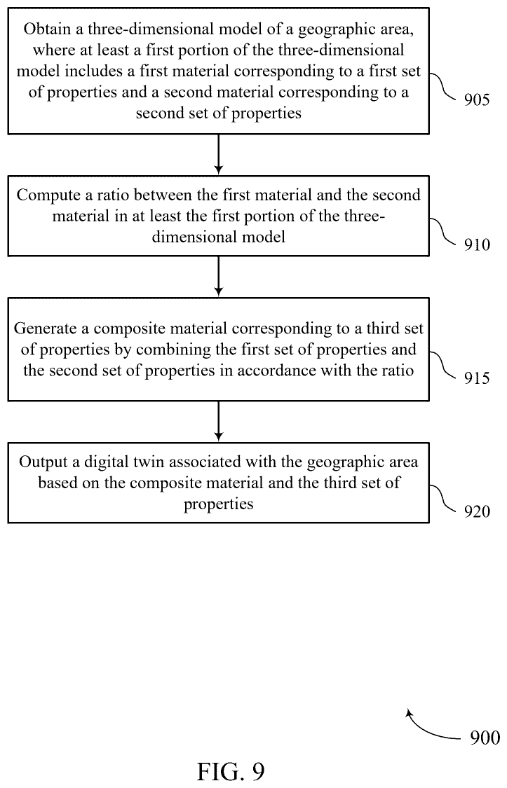

FIG. 9 shows a flowchart illustrating a method 900 that supports creating composite material properties for digital twin based wireless simulation in accordance with one or more aspects of the present disclosure. The operations of the method 900 may be implemented by a digital twin server or its components as described herein. For example, the operations of the method 900 may be performed by a digital twin server as described with reference to FIGS. 1 through 8. In some examples, a digital twin server may execute a set of instructions to control the functional elements of the UE or the network entity to perform the described functions. Additionally, or alternatively, the digital twin server may perform aspects of the described functions using special-purpose hardware.

At 905, the method may include obtaining a three-dimensional model of a geographic area, where at least a first portion of the three-dimensional model includes a first material corresponding to a first set of properties and a second material corresponding to a second set of properties. The operations of 905 may be performed in accordance with examples as disclosed herein. In some examples, aspects of the operations of 905 may be performed by a model manager 625 as described with reference to FIG. 6.

At 910, the method may include computing a ratio between the first material and the second material in at least the first portion of the three-dimensional model. The operations of 910 may be performed in accordance with examples as disclosed herein. In some examples, aspects of the operations of 910 may be performed by a ratio manager 630 as described with reference to FIG. 6.

At 915, the method may include generating a composite material corresponding to a third set of properties by combining the first set of properties and the second set of properties in accordance with the ratio. The operations of 915 may be performed in accordance with examples as disclosed herein. In some examples, aspects of the operations of 915 may be performed by a composite material manager 635 as described with reference to FIG. 6.

At 920, the method may include outputting a digital twin associated with the geographic area based on the composite material and the third set of properties. The operations of 920 may be performed in accordance with examples as disclosed herein. In some examples, aspects of the operations of 920 may be performed by a digital twin manager 640 as described with reference to FIG. 6.

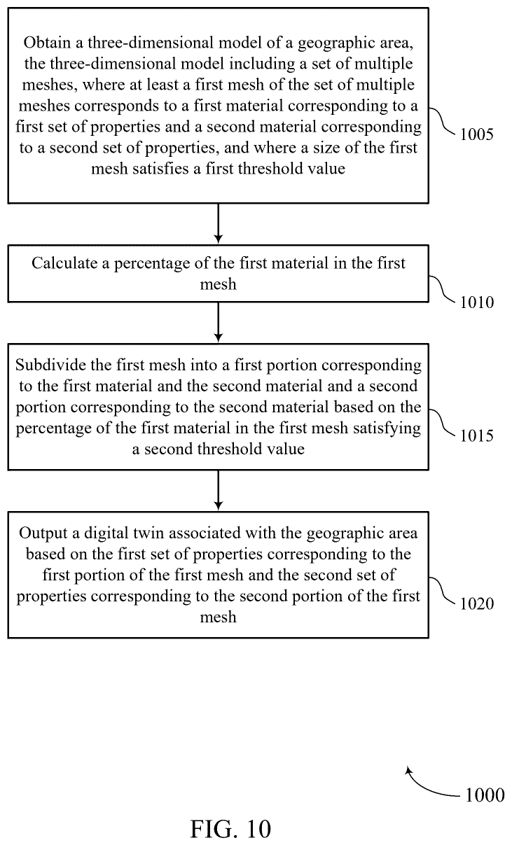

FIG. 10 shows a flowchart illustrating a method 1000 that supports creating composite material properties for digital twin based wireless simulation in accordance with one or more aspects of the present disclosure. The operations of the method 1000 may be implemented by a digital twin server or its components as described herein. For example, the operations of the method 1000 may be performed by a digital twin server as described with reference to FIGS. 1 through 8. In some examples, a digital twin server may execute a set of instructions to control the functional elements of the digital twin server to perform the described functions. Additionally, or alternatively, the digital twin server may perform aspects of the described functions using special-purpose hardware.

At 1005, the method may include obtaining a three-dimensional model of a geographic area, the three-dimensional model including a set of multiple meshes, where at least a first mesh of the set of multiple meshes corresponds to a first material corresponding to a first set of properties and a second material corresponding to a second set of properties, and where a size of the first mesh satisfies a first threshold value. The operations of 1005 may be performed in accordance with examples as disclosed herein. In some examples, aspects of the operations of 1005 may be performed by a model manager 625 as described with reference to FIG. 6.

At 1010, the method may include calculating a percentage of the first material in the first mesh. The operations of 1010 may be performed in accordance with examples as disclosed herein. In some examples, aspects of the operations of 1010 may be performed by a material percentage manager 645 as described with reference to FIG. 6.

At 1015, the method may include subdividing the first mesh into a first portion corresponding to the first material and the second material and a second portion corresponding to the second material based on the percentage of the first material in the first mesh satisfying a second threshold value. The operations of 1015 may be performed in accordance with examples as disclosed herein. In some examples, aspects of the operations of 1015 may be performed by a subdivision manager 650 as described with reference to FIG. 6.

At 1020, the method may include outputting a digital twin associated with the geographic area based on the first set of properties corresponding to the first portion of the first mesh and the second set of properties corresponding to the second portion of the first mesh. The operations of 1020 may be performed in accordance with examples as disclosed herein. In some examples, aspects of the operations of 1020 may be performed by a digital twin manager 640 as described with reference to FIG. 6.

The following provides an overview of aspects of the present disclosure:

Aspect 1: A method for digital twin creation, comprising: obtaining a three-dimensional model of a geographic area, wherein at least a first portion of the three-dimensional model comprises a first material corresponding to a first set of properties and a second material corresponding to a second set of properties; computing a ratio between the first material and the second material in at least the first portion of the three-dimensional model; generating a composite material corresponding to a third set of properties by combining the first set of properties and the second set of properties in accordance with the ratio; and outputting a digital twin associated with the geographic area based at least in part on the composite material and the third set of properties.

Aspect 2: The method of aspect 1, further comprising: assigning the composite material corresponding to the third set of properties to at least the first portion of the three-dimensional model, wherein outputting the digital twin is based at least in part on the assigning.

Aspect 3: The method of any of aspects 1 through 2, wherein computing the composite material comprises: generating a model of the composite material corresponding to the third set of properties via a machine learning model.

Aspect 4: The method of any of aspects 1 through 3, further comprising: obtaining the first set of properties corresponding to the first material and the second set of properties for responding to the second material from a database, wherein generating the composite material corresponding to the third set of properties is based at least in part on obtaining the first set of properties and the second set of properties from the database.

Aspect 5: The method of aspect 4, further comprising: obtaining a first plurality of measurements corresponding to the first material, the first set of properties based at least in part on the first plurality of measurements; obtaining a second plurality of measurements corresponding to the second material, the second set of properties based at least in part on the second plurality of measurements; and storing the first set of properties and the second set of properties in the database based on obtaining the first plurality of measurements and the second plurality of measurements.

Aspect 6: The method of any of aspects 1 through 5, wherein the first material and the second material are internal or external to one or more structures of the three-dimensional model.

Aspect 7: A method for digital twin creation, comprising: obtaining a three-dimensional model of a geographic area, the three-dimensional model comprising a plurality of meshes, wherein at least a first mesh of the plurality of meshes corresponds to a first material corresponding to a first set of properties and a second material corresponding to a second set of properties, and wherein a size of the first mesh satisfies a first threshold value; calculating a percentage of the first material in the first mesh; subdividing the first mesh into a first portion corresponding to the first material and the second material and a second portion corresponding to the second material based at least in part on the percentage of the first material in the first mesh satisfying a second threshold value; and outputting a digital twin associated with the geographic area based at least in part on the first set of properties corresponding to the first portion of the first mesh and the second set of properties corresponding to the second portion of the first mesh.

Aspect 8: The method of aspect 7, further comprising: assigning the first set of properties to the first portion of the first mesh; and assigning the second set of properties to the second portion of the first mesh, wherein the digital twin is based at least in part on assigning the first set of properties to the first portion of the first mesh and assigning the second set of properties to the second portion of the first mesh.

Aspect 9: The method of any of aspects 7 through 8, wherein subdividing the first mesh comprises: subdividing the first mesh multiple times until a size of the resulting subdivision of the first mesh fails to satisfy the first threshold, or the percentage of the first material in a resulting subdivision of the first mesh fails to satisfy the second threshold value.

Aspect 10: The method of any of aspects 7 through 9, wherein subdividing the first mesh comprises: subdividing the first mesh based on an object boundary within the first mesh.

Aspect 11: The method of any of aspects 7 through 10, wherein subdividing the first mesh comprises: subdividing the first mesh based on a mathematical division into equal portions.

Aspect 12: An apparatus for digital twin creation, comprising one or more memories storing processor-executable code, and one or more processors coupled with the one or more memories and individually or collectively operable to execute the code to cause the apparatus to perform a method of any of aspects 1 through 6.

Aspect 13: An apparatus for digital twin creation, comprising at least one means for performing a method of any of aspects 1 through 6.

Aspect 14: A non-transitory computer-readable medium storing code for digital twin creation, the code comprising instructions executable by one or more processors to perform a method of any of aspects 1 through 6.

Aspect 15: An apparatus for digital twin creation, comprising one or more memories storing processor-executable code, and one or more processors coupled with the one or more memories and individually or collectively operable to execute the code to cause the apparatus to perform a method of any of aspects 7 through 11.

Aspect 16: An apparatus for digital twin creation, comprising at least one means for performing a method of any of aspects 7 through 11.

Aspect 17: A non-transitory computer-readable medium storing code for digital twin creation, the code comprising instructions executable by one or more processors to perform a method of any of aspects 7 through 11.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
one or more memories storing processor-executable code; and
one or more processors coupled with the one or more memories and individually or collectively operable to execute the code to cause the apparatus to:
obtain a three-dimensional model of a geographic area, wherein at least a first portion of the three-dimensional model comprises a first material corresponding to a first set of properties and a second material corresponding to a second set of properties;
compute a ratio between the first material and the second material in at least the first portion of the three-dimensional model;
generate a composite material corresponding to a third set of properties by combining the first set of properties and the second set of properties in accordance with the ratio; and
output a digital twin associated with the geographic area based at least in part on the composite material and the third set of properties.

2. The apparatus of claim 1, wherein the one or more processors are individually or collectively further operable to execute the code to cause the apparatus to:
assign the composite material corresponding to the third set of properties to at least the first portion of the three-dimensional model, wherein outputting the digital twin is based at least in part on the assigning.

3. The apparatus of claim 1, wherein, to compute the composite material, the one or more processors are individually or collectively operable to execute the code to cause the apparatus to:
generate a model of the composite material corresponding to the third set of properties via a machine learning model.

4. The apparatus of claim 1, wherein the one or more processors are individually or collectively further operable to execute the code to cause the apparatus to:
obtain the first set of properties corresponding to the first material and the second set of properties for responding to the second material from a database, wherein generating the composite material corresponding to the third set of properties is based at least in part on obtaining the first set of properties and the second set of properties from the database.

5. The apparatus of claim 4, wherein the one or more processors are individually or collectively further operable to execute the code to cause the apparatus to:
obtain a first plurality of measurements corresponding to the first material, the first set of properties based at least in part on the first plurality of measurements;
obtain a second plurality of measurements corresponding to the second material, the second set of properties based at least in part on the second plurality of measurements; and
store the first set of properties and the second set of properties in the database based on obtaining the first plurality of measurements and the second plurality of measurements.

6. The apparatus of claim 1, wherein the first material and the second material are internal or external to one or more structures of the three-dimensional model.

7. An apparatus, comprising:
one or more memories storing processor-executable code; and
one or more processors coupled with the one or more memories and individually or collectively operable to execute the code to cause the apparatus to:
obtain a three-dimensional model of a geographic area, the three-dimensional model comprising a plurality of meshes, wherein at least a first mesh of the plurality of meshes corresponds to a first material corresponding to a first set of properties and a second material corresponding to a second set of properties, and wherein a size of the first mesh satisfies a first threshold value;
calculate a percentage of the first material in the first mesh;
subdivide the first mesh into a first portion corresponding to the first material and the second material and a second portion corresponding to the second material based at least in part on the percentage of the first material in the first mesh satisfying a second threshold value; and
output a digital twin associated with the geographic area based at least in part on the first set of properties corresponding to the first portion of the first mesh and the second set of properties corresponding to the second portion of the first mesh.

8. The apparatus of claim 7, wherein the one or more processors are individually or collectively further operable to execute the code to cause the apparatus to:
assign the first set of properties to the first portion of the first mesh; and
assign the second set of properties to the second portion of the first mesh, wherein the digital twin is based at least in part on assigning the first set of properties to the first portion of the first mesh and assigning the second set of properties to the second portion of the first mesh.

9. The apparatus of claim 7, wherein, to subdivide the first mesh, the one or more processors are individually or collectively operable to execute the code to cause the apparatus to:
subdivide the first mesh multiple times until a size of the resulting subdivision of the first mesh fails to satisfy the first threshold, or the percentage of the first material in a resulting subdivision of the first mesh fails to satisfy the second threshold value.

10. The apparatus of claim 7, wherein, to subdivide the first mesh, the one or more processors are individually or collectively operable to execute the code to cause the apparatus to:
subdivide the first mesh based on an object boundary within the first mesh.

11. The apparatus of claim 7, wherein, to subdivide the first mesh, the one or more processors are individually or collectively operable to execute the code to cause the apparatus to:
subdivide the first mesh based on a mathematical division into equal portions.

12. A method for digital twin creation, comprising:
obtaining a three-dimensional model of a geographic area, wherein at least a first portion of the three-dimensional model comprises a first material corresponding to a first set of properties and a second material corresponding to a second set of properties;
computing a ratio between the first material and the second material in at least the first portion of the three-dimensional model;
generating a composite material corresponding to a third set of properties by combining the first set of properties and the second set of properties in accordance with the ratio; and
outputting a digital twin associated with the geographic area based at least in part on the composite material and the third set of properties.

13. The method of claim 12, further comprising:
assigning the composite material corresponding to the third set of properties to at least the first portion of the three-dimensional model, wherein outputting the digital twin is based at least in part on the assigning.

14. The method of claim 12, wherein computing the composite material comprises:
generating a model of the composite material corresponding to the third set of properties via a machine learning model.

15. The method of claim 12, further comprising:
obtaining the first set of properties corresponding to the first material and the second set of properties for responding to the second material from a database, wherein generating the composite material corresponding to the third set of properties is based at least in part on obtaining the first set of properties and the second set of properties from the database.

16. The method of claim 15, further comprising:
obtaining a first plurality of measurements corresponding to the first material, the first set of properties based at least in part on the first plurality of measurements;
obtaining a second plurality of measurements corresponding to the second material, the second set of properties based at least in part on the second plurality of measurements; and
storing the first set of properties and the second set of properties in the database based on obtaining the first plurality of measurements and the second plurality of measurements.

17. The method of claim 12, wherein the first material and the second material are internal or external to one or more structures of the three-dimensional model.
